(19) United States
(12) Patent Application Publication
(10) Pub. No.: US 2009/0194028 A1
(43) Pub. Date: Aug. 6, 2009

(54) PLASMA PROCESSING DEVICE

(76) Inventors: Koichi FUKUDA, Miyagi-ken (JP); Donggil Kim, Miyagi-ken (JP); Tadahiro Ohmi, Miyagi-ken (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/368,487

(22) Filed: Feb. 10, 2009

Related U.S. Application Data
(63) Continuation of application No. 08/652,284, filed on May 21, 1996, now abandoned.

(30) Foreign Application Priority Data
May 25, 1995 (JP) 7-126276

(51) Int. Cl. C23C 16/54

(52) U.S. Cl. 118/723 E

(57) ABSTRACT

A plasma processing device of the type comprises an RF electrode which is made of a metal and is covered with a ceramic material at least at a portion of the metal exposed to a plasma. The RF electrode is so controlled that a discharge amount of a gas generated therefrom is in the range of 10⁻⁸ Torr·L/second to 10⁻⁶ Torr·L/second. To this end, the ceramic material is favorably made of a sintered ceramic material.

### BACKGROUND OF THE INVENTION

This invention relates to a plasma processing device.

A plasma processing device known in the art includes one which utilizes, as an electrode, an RF electrode whose metallic surface is plasma spray-coated with ceramic materials such as alumina. When film formation is performed by using this known plasma processing device, limitation is placed on the characteristics of the resulting film. For instance, if a dielectric film is formed, its dielectric breakdown strength is limited to a level as small as 8 MV/cm.

The RF electrode is, in most cases, formed with fine openings such as gas injection ports. When using spray coating, a difficulty has been experienced in coating the inner surfaces of the fine openings. Accordingly, the inner surfaces of the individual holes are liable to be attacked with the plasma, thereby causing the film-forming atmosphere to be polluted.

### SUMMARY OF THE INVENTION

It is an object of the invention to provide a plasma processing device which is able to form a film having good characteristics.

It is another object of the invention to provide a plasma processing device which comprises an RF electrode having fine openings covered with a ceramic material on inner surfaces thereof whereby a film-forming atmosphere is prevented from contamination.

The plasma processing device in this invention is characterized by comprising an RF electrode which is made of a metal and is covered with a ceramic material at least at a portion of the metal exposed to a plasma, wherein a discharge amount of a gas generated from the RF electrode is so controlled as to be in the range of 10⁻⁸ Torr·L/second to 10⁻⁶ Torr·L/second.

Preferably, the ceramic material used above consists of a sintered ceramic material.

The plasma processing device in this invention is characterized by comprising an RF electrode which is made of a metal and is covered with a ceramic material at least at a portion of the metal exposed to a plasma, the ceramic material consists essentially of a sintered ceramic material.

The sintered ceramic material is preferably made of alumina or zirconium oxide. The metal used as the RF electrode is preferably made of tungsten or molybdenum. Moreover, the RF electrode should preferably have a number of fine openings.

### BRIEF DESCRIPTION OF THE INVENTION

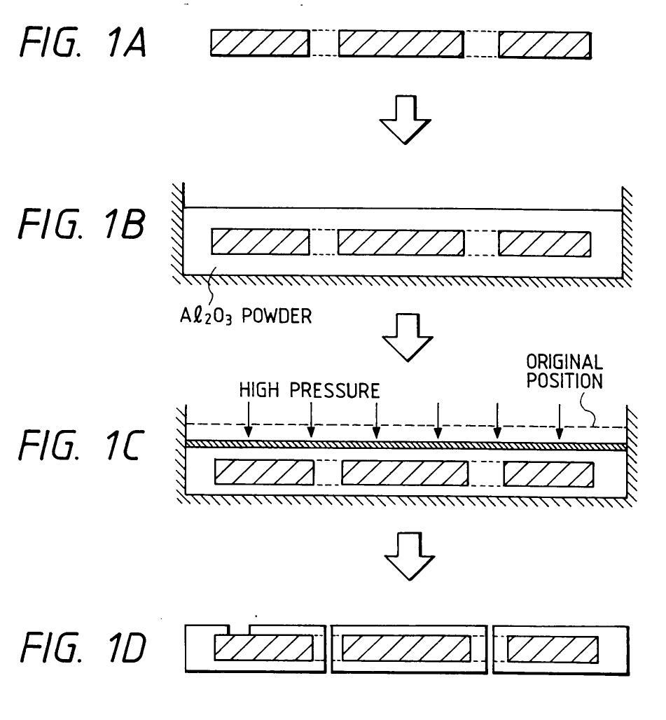

FIGS. 1A, 1B, 1C and 1D are, respectively, views showing a series of steps of fabricating an RF electrode used in a plasma processing device of the invention;

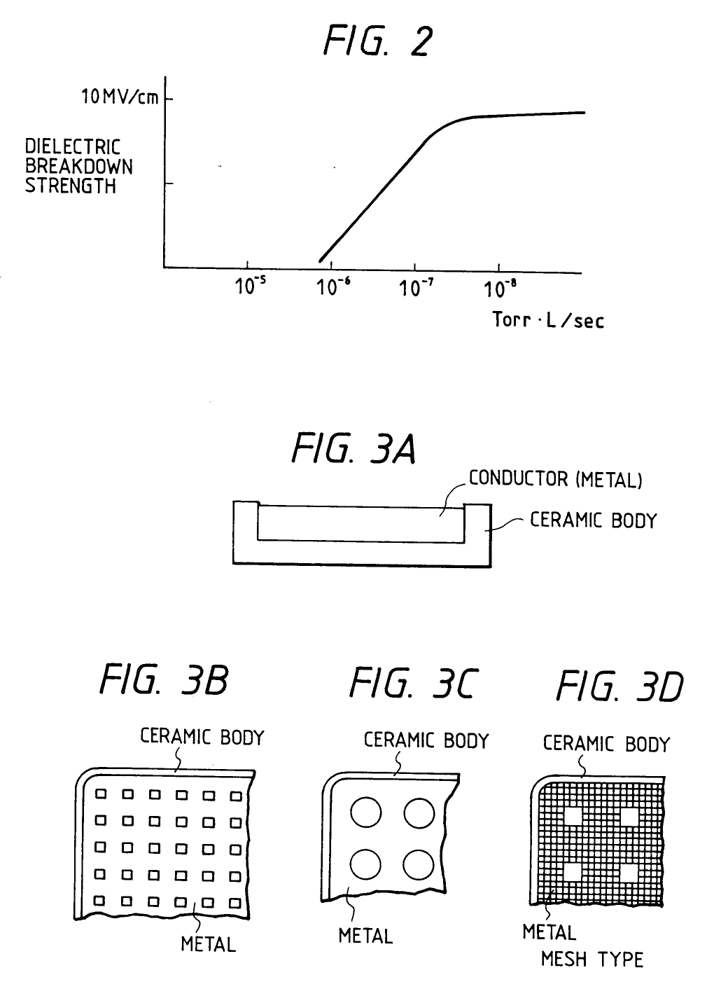

FIG. 2 is a graph showing the relation between the dielectric breakdown strength and the amount of a discharged gas; and

FIGS. 3A, 3B, 3C and 3D are, respectively, schematic views showing RF electrodes according to the invention.

### PREFERRED EMBODIMENTS OF THE INVENTION

Using plasma processing devices, a variety of films such as semiconductor films, dielectric films and the like are formed. In order to attain good characteristic properties such as, for example, a high dielectric breakdown strength for dielectric films, and high mobility for semiconductor films, the concentration of impurities in starting gases should be reduced to a level on the order of ppb. Moreover, the inner walls of a film-forming chamber of a plasma processing device should be made of a material, which exhibits only a reduced amount of a gas discharged from the inner wall surfaces, e.g. a stainless steel having on the surface thereof an oxide passive film made of chromium oxide. Thus, the impurity concentration can be reduced to a minimum.

In spite of the fact that the impurity concentration is thus caused to reduce to an extent as small as possible, it has not been possible to form a film having good characteristics by use of known plasma processing devices.

In order to clarify the reason for this, we made studies and, as a result, found that the discharge of gases from an RF electrode created one of great causes therefor. More importantly, it was found that the characteristics were sharply improved when the discharge amount is at a level of 10⁻⁶ Torr·L/second or below. In other words, the value of 10⁻⁶ Torr·L/second is critical. When the discharge amount is 10⁻⁶ Torr·L/second or below, there can be formed a film whose characteristics are good.

Preferably, the discharge amount of a gas is 10⁻⁷ Torr·L/second or below.

In this connection, however, when the amount is at a level of 5×10⁻⁸ Torr·L/second, the effect such as on dielectric breakdown strength is saturated. Accordingly, the lower limit is 5×10⁻⁸ Torr·L/second in economy.

It has also been found that in order to reduce the gas discharge, ceramic materials for covering an RF electrode made of a metal should preferably be made of sintered ceramics. This is because the sintered ceramics are much lower in the gas discharge amount than conventionally employed sprayed ceramics. The sintered ceramics can remarkably reduce an amount of the gas discharged from the RF electrode over the prior art cases. Thus, films can be formed as having good characteristics.

The reason why sintered ceramics enables a remarkable reduction in amount of discharged gas over sprayed ceramics is not clearly known. It is assumed that the detailed observation of conventionally employed sprayed ceramics in the surfaces thereof reveals the presence of voids; and the voids serve as a site for keeping an impurity gas therein and thus act as a discharge gas source. In contrast, sintered ceramics have no voids in the surface thereof. This seems to be the reason why the amount of a discharged gas is smaller than in the case of sprayed ceramics.

The sintered ceramics are ones which are formed through a sintering process. The sintering process includes, for example, a HP process (pressure sintering process), an SPS process (spark plasma sintering process), an HIP process (hot isostatic press sintering process) and the like. The discharge amount of gas attained by these processes is at a level of 10⁻⁷ Torr·L/second for the HP process, at a level of 10⁻⁸ Torr·L/second for the SPS process, and at a level of 10⁻⁹ Torr·L/second for the HIP process.

The type of ceramic used is not critical and preferably includes alumina, zirconium oxide (i.e. zirconia) or the like. Alumina or zirconium oxide has good corrosion and plasma resistances and is less susceptible to contamination with impurities from the electrode than other types of ceramics. Thus, the resultant film has better characteristics.

Known RF electrodes are usually made of Hastelloy (registered trade name). Sintering of ceramics is conducted under high pressure and high temperature conditions. It has been found that when Hastelloy is used for this purpose, it is apt to crack. Tungsten, tantalumn or molybdenum can effectively prevent from cracking and is preferred.

With sprayed ceramics, it is difficult to coat therewith the inner surfaces of fine openings, such as gas injection ports as having stated hereinbefore. In contrast, sintered ceramics are effective in coating fine openings of an RF electrode.

For the coating, a metal substrate is formed, in position, with fine openings, such as injection ports, as having a diameter of (a+α) which is greater by a than a designed diameter, (a). Thereafter, a ceramic material is applied to and sintered on the metal substrate including the openings, followed by forming in position fine openings having a diameter, (a), such as by a laser beam. In this manner, the sintered ceramic layer with a thickness of α/2 can be formed on the inner surfaces of the individual fine openings. Because the value of α is not critical, the sintered ceramic layer having a desired thickness can be formed on the inner surfaces of individual openings.

The invention is more particularly described by way of examples.

### Example 1

A tungsten (W) plate having 30 cm square and a thickness of 5 mm was provided. This metallic plate had a surface roughness, Ra, of 30 nm.

The plate was punched to form openings each having a diameter of 3 mm. This is particularly shown in FIG. 1A.

As shown in FIG. 1B, the plate was placed in a mold along with alumina (Al₂O₃) powder. The powder had an average particle size of 100 μm and a purity of 99.9%.

As shown in FIG. 1C, the powder was sintered under high pressure and high temperature conditions according to an HP process. The pressure was 30 MPa and the temperature was 1500° C. The sintering time was 2 hours.

After completion of the sintering, the resultant electrode was removed from the mold as shown in FIG. 1D. Holes or openings (0.3 mm in diameter) for gas injection were formed in the respective holes formed in FIG. 1A by means of a laser beam along with a hole to expose the metal plate, through which RF power was applied.

In this manner, ten RF electrodes were made and each subjected to measurement of a gas discharge characteristic, with the result that the characteristic was in the range of about 10⁻⁶ to 5×10⁻⁷ Torr·L/second.

The thus obtained RF electrode was used to make a plasma processing device. The plasma processing device had a film-forming chamber. This chamber was made of stainless steel which had inner walls whose surface was made of a passive film of chromium oxide. The amount of a gas discharged from the inner walls was set at 10⁻⁸ to 10⁻⁷ Torr·L/second. Using this plasma processing device, a silicon nitride film was formed according to a plasma enhanced CVD process. It will be noted that the concentration of impurities in starting gases was reduced to a level of several ppb or below. Prior to the film formation, nitrogen gas was used for purging in a batchwise manner. The resultant silicon nitride film was subjected to measurement of dielectric breakdown strength, revealing that the dielectric breakdown strength was 8.0 to 9.0 MV/cm.

### Example 2

The general procedure of Example 1 was repeated using an SPS process. The gas discharge characteristic was found to be 5×10⁻⁷ to 5×10⁻⁸ Torr·L/second. The dielectric breakdown strength was found to be 9.0 to 9.5 MV/cm.

### Example 3

The general procedure of Example 1 was repeated using an HIP process. The gas discharge characteristic was found to be 5×10⁻⁸ to 5×10⁻⁹ Torr·L/second. The dielectric breakdown strength was found to be 9.5 to 10.0 MV/cm.

FIG. 2 shows the results of the dielectric breakdown strength measured in Examples 1 to 3. As will be apparent from the FIG. 2, the dielectric breakdown strength sharply increases from 10⁻⁶ Torr·L/second. Moreover, the breakdown strength is saturated over 5×10⁻⁸ Torr·L/second.

### Example 4

In this example, an RF electrode of the type shown in FIG. 3A was fabricated according to the HP process under the same conditions as in Example 1. This RF electrode was constituted of a recessed ceramic body and a metallic body fixedly mounted in or bonded to the ceramic body.

After fabrication of the recessed ceramic body by sintering, the ceramic body and a molybdenum (Mo) plate were bonded together by means of a bonding agent commercially available under the designation of Ceraset SN (registered trade name).

This electrode had a gas discharge characteristic of 5×10⁻⁶ Torr·L/second to 10⁻⁷ Torr·L/second, and a dielectric breakdown strength of 8.0 to 9.0 MV/cm.

### Example 5

RF electrodes of the types shown in FIGS. 3B, 3C and 3D, respectively, were fabricated in this example. Each ceramic body was made according to the HP process and the metal used was tungsten. The electrodes were made in the same manner as in Example 1.

As is particularly shown in FIGS. 3B and 3C, the metallic plate may be formed with openings of different forms in order to diminish the difference in thermal expansion between the ceramic body and the metallic plate. Moreover, as shown in FIG. 3D, a mesh made of metallic threads may be used in place of the perforated metallic plate.

What is claimed is:

1. A plasma processing device of the type which comprises an RF electrode made of a metal and covered with a ceramic material at least at a portion of the metal exposed to a plasma, wherein a discharge amount of a gas generated from the RF electrode is so controlled as to be in the range of 10⁻⁸ Torr·L/second to 10⁻⁶ Torr·L/second.

2. A plasma processing device according to claim 1, wherein said ceramic material consists essentially of a sintered ceramic material.

3. A plasma processing device of the type which comprises an RF electrode made of a metal and covered with a ceramic material at least at a portion of the metal exposed to a plasma, wherein said ceramic material consists essentially of a sintered ceramic material.

4. A plasma processing device according to claim 3, wherein said sintered ceramic material is a member selected from the group consisting of alumina and zirconium oxide.

5. A plasma processing device according to claim 3 or 4, wherein said metal is a member selected from the group consisting of tungsten or molybdenum.

6. A plasma processing device according to any one of claims 3 to 5, wherein said RF electrode has a number of fine openings.
